(19) United States
(12) Patent Application Publication
(10) Pub. No.: US 2006/0246293 A1
(43) Pub. Date: Nov. 2, 2006

(54) Substrate for organic electroluminescence element

(75) Inventors: Yasuhiro Iizumi, Tokyo (JP); Norihito Ito, Tokyo (JP)

Correspondence Address: SEYFARTH SHAW LLP, 131 S. DEARBORN ST., SUITE2400, CHICAGO, IL, 60603-5803, US

(73) Assignee: Dai Nippon Printing Co., Ltd.

(21) Appl. No.: 11/411,646

(22) Filed: Apr. 26, 2006

(30) Foreign Application Priority Data
Apr. 27, 2005 (JP) 2005-129929

(51) Int. Cl. H01L 51/52; H05B 33/12

(52) U.S. Cl. 428/411.1; 428/690; 428/917; 313/504; 313/506

(57) ABSTRACT

The main object of the present invention is to provide a substrate for an organic EL element using a photocatalyst containing layer, capable of providing an organic EL element having the excellent light emission characteristic. To achieve the object, the invention provides a substrate for an organic EL element comprising a base material, an electrode layer formed on the base material, a photocatalyst containing layer formed on the electrode layer, and a smoothing layer formed on the photocatalyst containing layer.

### BACKGROUND OF THE INVENTION

1. Field of the Invention

The present invention relates to a substrate for an organic electroluminescence element using a photocatalyst containing layer.

2. Description of the Related Art

An organic electroluminescence (hereinafter, it may be abbreviated as the EL) element attracts the attention for the use as a self light emitting type display. In particular, since an organic EL display has a high light emitting efficiency of obtaining a high luminance light emission with the applied voltage of 10 V or less, or the like, and furthermore, the light emission can be carried out with a simple element structure, its application to an advertisement for the light emission and the display of a specific pattern, and the other simple displays of a low price is expected.

However, at the time of actually producing an organic EL display, patterning of an electrode layer and a light emitting layer is required so that typically a photolithography process and a patterning process by a complicated film forming device are needed so as to cause the process complication and the cost rise. Moreover, according to a mask deposition method, an expensive vacuum chamber is needed so that the problems of the yield and the equipment cost are involved.

In order to solve the problems, a method of using a photocatalyst containing layer for patterning a light emitting layer, or the like has been proposed (for example, see the official gazettes of the Japanese Patent Application Laid-Open (JP-A) Nos. 2001-257073, 2002-231446). The method is for changing the surface wettability by the pattern exposure of a photocatalyst containing layer so as to pattern a light emitting layer, or the like, utilizing the pattern with a different wettability. According to the method, the minute patterning operation can be enabled more easily and accurately.

However, since a photocatalyst such as a titanium oxide contained in the photocatalyst containing layer is in general granular, or the like, the surface state of the photocatalyst containing layer is coarse so that the average surface roughness (Ra) may be 10 nm or more, or the maximum height difference (P−V) may be 100 nm or more. Therefore, the barrier at the interface between the light emitting layer and the photocatalyst containing layer is made larger so as to disturb the charge transfer. Accordingly, a problem is involved in that the light emission characteristic is made lower. Moreover, due to the surface state coarseness of the photocatalyst containing layer, the problems are involved in that the film thickness irregularity is generated in a light emitting layer having a relatively thin thickness, and the short circuit is generated between the electrodes.

### SUMMARY OF THE INVENTION

In view of the above-mentioned problems, the present invention has been achieved. The main object of the invention is to provide a substrate for an organic EL element using a photocatalyst containing layer, capable of providing an organic EL element having the excellent light emission characteristic.

As a result of the elaborate discussion of the above-mentioned circumstances, the present inventors have found out that the light emission characteristic of an organic EL element can be improved by providing a smoothing layer between a photocatalyst containing layer and a light emitting layer so as to complete the present invention.

That is, the present invention provides a substrate for an organic EL element comprising a base material, an electrode layer formed on the above-mentioned base material, a photocatalyst containing layer formed on the above-mentioned electrode layer, and a smoothing layer formed on the above-mentioned photocatalyst containing layer.

According to the present invention, since the smoothing layer is formed on the photocatalyst containing layer, in the case a substrate for an organic EL element of the present invention is used for an organic EL element, the barrier can be reduced at the interface between the photocatalyst containing layer and the smoothing layer and the interface between the smoothing layer and the light emitting layer. Therefore, by using the substrate for an organic EL element of the present invention, the light emission characteristic can be improved. Moreover, since the smoothing layer is formed on the photocatalyst containing layer, in the case the substrate for an organic EL element of the present invention is used for an organic EL element, a light emitting layer and a counter electrode layer with an even film thickness can be obtained. Therefore, short circuit between the electrodes can be prevented.

According to the above-mentioned invention, it is preferable that the above-mentioned smoothing layer has the charge transporting property. Thereby, the charge injected from the electrode layer can be transported smoothly to the light emitting layer. Therefore, by using the substrate for an organic EL element of the present invention, the light emitting efficiency can be improved.

Moreover, according to the present invention, the above-mentioned photocatalyst containing layer may be a photocatalyst containing wettability changeable layer containing a photocatalyst so as to have a wettability change by a function of the photocatalyst accompanied by an energy irradiation. Since the photocatalyst containing layer has the wettability change by the function of the photocatalyst accompanied by the energy irradiation, the following can be enabled: the smoothing layer having the charge transporting property can easily be patterned; and in the case the substrate for an organic El element of the present invention is used for an organic EL element, the light emitting layer, or the like can be patterned easily. Moreover, since the above-mentioned photocatalyst containing wettability changeable layer has the wettability change by the function of the photocatalyst contained in the layer itself, the wettability can be changed efficiently.

Moreover, the above-mentioned photocatalyst containing layer may have a photocatalyst processing layer containing a photocatalyst and a wettability changeable layer with the wettability changed by the function of the photocatalyst accompanied by the energy irradiation. Also in this case, since the wettability changeable layer in the photocatalyst containing layer has the wettability change by the function of the photocatalyst accompanied by the energy irradiation, the patterning characteristic can be improved. Moreover, since the photocatalyst containing layer of the above-mentioned configuration has layers separated per function, it is advantageous in that the combination of the layer configuration and the material, or the like can easily be changed.

Furthermore, according to the present invention, it is preferable that the average surface roughness (Ra) of the above-mentioned smoothing layer is less than 10 nm. Since the average surface roughness (Ra) is in the above-mentioned range, in the case the substrate for an organic EL element is used for an organic EL element, the light emission characteristic can be improved effectively.

Moreover, according to the present invention, it is preferable that the maximum height difference (P−V) of the above-mentioned smoothing layer is less than 100 nm. Since the maximum height difference is in the above-mentioned range, as in the above-mentioned case, in the case the substrate for an organic EL element of the present invention is used for an organic EL element, the light emission characteristic can be improved effectively.

Moreover, the present invention provides an organic EL element comprising the above-mentioned substrate for an organic EL element, an organic EL layer having at least a light emitting layer and formed on the smoothing layer of the above-mentioned substrate for an organic EL element, and a counter electrode layer formed on the above-mentioned organic EL layer.

According to the present invention, since the above-mentioned substrate for an organic EL element is used, an organic EL element having the excellent light emission characteristic can be obtained.

According to the present invention, since the smoothing layer is formed on the photocatalyst containing layer, in the case such a substrate for an organic EL element is used for an organic EL element, the effects of improving the light emission characteristic and improving the patterning characteristics can be provided.

### BRIEF DESCRIPTION OF THE DRAWINGS

FIG. 1 is a schematic cross-sectional view showing an example of a substrate for an organic EL element of the present invention.

FIGS. 2A to 2C is a process diagram showing an example of a production method for a substrate for an organic EL element of the present invention.

FIGS. 3A to 3C is a process diagram showing another example of a production method for a substrate for an organic EL element of the present invention.

FIG. 4 is a schematic cross-sectional view showing an example of an organic EL element of the present invention.

FIG. 5 is a graph showing the light emitting efficiency-voltage characteristic of the organic EL elements of the examples 1 to 3 and the comparative example 1.

FIG. 6 is a graph showing the life property of the organic EL elements of the examples 1 to 3 and the comparative example 1.

### DESCRIPTION OF THE PREFERRED EMBODIMENT

Hereinafter, the substrate for an organic EL element and the organic EL element of the present invention will be explained in detail.

A. Substrate for an Organic EL Element

First, a substrate for an organic EL element of the present invention will be explained.

The substrate for an organic EL element of the present invention comprises a base material, an electrode layer formed on the above-mentioned base material, a photocatalyst containing layer formed on the above-mentioned electrode layer, and a smoothing layer formed on the above-mentioned photocatalyst containing layer.

The substrate for an organic EL element of the present invention will be explained with reference to the drawings.

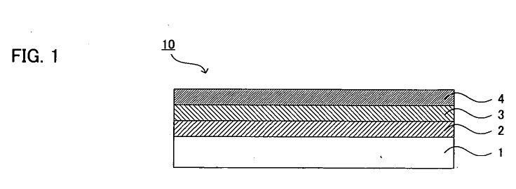

FIG. 1 is a schematic cross-sectional view showing an example of a substrate for an organic EL element of the present invention. As shown in FIG. 1, the substrate for an organic EL element 10 of the present invention comprises an electrode layer 2, a photocatalyst containing layer 3 and a smoothing layer 4 formed successively on a base material 1.

According to the present invention, since the smoothing layer is formed on the photocatalyst containing layer so that the surface state of the photocatalyst containing layer can be improved by the smoothing layer. Thereby, in the case the substrate for an organic EL element of the present invention is used for an organic EL element, the light emitting layer can be formed evenly on the smoothing layer so that the barrier at the interface between the photocatalyst containing layer and the smoothing layer, and the barrier at the interface between the smoothing layer and the light emitting layer can be reduced. Therefore, by using the substrate for an organic EL element of the present invention, the light emission characteristic can be improved by reducing the driving voltage, improving the light emitting intensity and the light emitting efficiency, or the like.

Moreover, in the case the substrate for an organic EL element of the present invention is used for an organic EL element, since the smoothing layer is formed on the photocatalyst containing layer, a light emitting layer and a counter electrode layer with an even film thickness can be provided to prevent short circuit between the electrodes.

Furthermore, in the case the substrate for an organic EL element is used for an organic EL element, since the smoothing layer is formed on the photocatalyst containing layer so that the photocatalyst containing layer and the light emitting layer cannot be contacted directly, deterioration of the light emitting materials in the light emitting layer caused by the photocatalyst can be restrained so as to achieve the longer lasting life as well as the light emitting efficiency.

Hereinafter, each configuration of the substrate for an organic EL element of the present invention will be explained.

1. Smoothing Layer

A smoothing layer used in the present invention is to be formed on a photocatalyst containing layer. According to the present invention, since the smoothing layer is provided, the surface state of the photocatalyst containing layer can be improved. Therefore, with the premise that the average surface roughness of the photocatalyst containing layer is Ra1 and the average surface roughness of the smoothing layer is Ra2, the correlationship is Ra2<Ra1.

The average surface roughness of the smoothing layer (Ra) is preferably less than 10 nm; more preferably 8 nm or less; and most preferably 2 nm or less. In the case the substrate for an organic EL element of the present invention is used for an organic EL element, although the light emitting layer, or the like is formed on the smoothing layer, since the surface state of the photocatalyst containing layer can be further improved by having the average surface roughness of the smoothing layer (Ra) in the above-mentioned range, the barrier at the interface of each layer from the photocatalyst containing layer to the light emitting layer can further be reduced so that the light emission characteristic can be improved effectively.

Moreover, with the premise that the maximum height difference of the photocatalyst containing layer is P−V1, and the maximum height difference of the smoothing layer is P−V2, the correlationship is P−V2<P−V1.

The maximum height difference of the smoothing layer (P−V) is preferably less than 100 nm; more preferably 80 nm or less; and most preferably 50 nm or less. As in the above-mentioned case, since the surface state of the photocatalyst containing layer can further be improved by having the maximum height difference of the smoothing layer (P−V) in the above-mentioned range, the barrier at the interface of each layer from the photocatalyst containing layer to the light emitting layer can further be reduced so that the light emission characteristic can be improved effectively.

The above-mentioned average surface roughness (Ra) and the maximum height difference (P−V) are the values measured by the 4 μm scanning range condition using a scanning type probe microscope (Nano Scope) produced by Digital Instruments.

Moreover, it is preferable that the smoothing layer used in the present invention has the charge transporting property. Thereby, the charge injected from the electrode layer can be transported smoothly to the light emitting layer. The charge transporting property may either be the hole transporting property or the electron transporting property, and it can be selected optionally according to whether the electrode layer is an anode or a cathode. For example, in the case the electrode layer is an anode, it is preferable that the smoothing layer has the hole transporting property. On the other hand, for example, in the case the electrode layer is a cathode, it is preferable that the smoothing layer has the electron transporting property.

In the case the smoothing layer has the hole transporting property, it is preferable to provide an electron blocking property for preventing penetration of the electron transported from the cathode at the time of using the substrate for an organic EL element of the present invention to an organic EL element. Thereby, the re-bonding efficiency of the holes and the electrons can be improved in the light emitting layer.

Specifically, it is preferable that the pseudo-electron affinity of the smoothing layer is smaller than the pseudo-electron affinity of the light emitting layer. Moreover, with the premise that the pseudo-electron affinity of the smoothing layer is Xp1, the ionizing potential of the smoothing layer is Ip1, and the pseudo-electron affinity of the light emitting layer is Xp2, the ionizing potential of the light emitting layer is Ip2, it is preferable that the correlationship is |Ip2−Ip1|<|Xp2−Xp1|.

The above-mentioned ionizing potential is a value (absolute value) measured with AC-1 produced by RIKEN KEIKI CO., LTD. Moreover, the above-mentioned pseudo-electron affinity is a value obtained by subtracting the band gap as the energy between the ionizing potential and the pseudo-electron affinity from the above-mentioned ionizing potential (absolute value) (pseudo-electron affinity=ionizing potential (absolute value)−band gap). The band gap is a value obtained by converting the wavelength (unit: nm) on the longest wavelength side of absorbing the electromagnetic wave at the time of directing an electromagnetic wave of a visible light beam or less of about less than 800 nm to the energy (unit: eV). Specifically, it is a value obtained by converting the wavelength λ (unit: nm) at the end part of the longest wavelength side of absorbing measured with an ultraviolet and visible spectrophotometer UV-3100 produced by Shimadzu Corporation to the energy (unit: eV) with the premise that 1 (eV)=1,240/λ (nm).

Furthermore, in the case the photocatalyst containing layer to be described later contains a photocatalyst and a binder, it is preferable that the energy gap of the smoothing layer is 2 eV or more. Thereby, the light emission characteristic can be improved. Although the reason of the improvement of the light emission characteristic is not always clear, it is considered that the pseudo-electron affinity of the smoothing layer is smaller than the pseudo-electron affinity of the light emitting layer so as to function as an electron blocking layer.

On the other hand, in the case the smoothing layer has the electron transporting property, it is preferable to have the hole blocking property for preventing penetration of the hole transferred from the anode at the time of using the substrate for an organic EL element of the present invention to an organic EL element. Thereby, the re-bonding efficiency of the holes and the electrons in the light emitting layer can be improved.

Specifically, it is preferable that the ionizing potential of the smoothing layer is smaller than the ionizing potential of the light emitting layer. Moreover, with the premise that the ionizing potential of the smoothing layer is Ip1, the pseudo-electron affinity of the smoothing layer is Xp1, and the ionizing potential of the light emitting layer is Ip2, the pseudo-electron affinity of the light emitting layer is Xp2, it is preferable that the correlationship is |Xp2−Xp1|<|Ip2−Ip1|.

The above-mentioned pseudo-electron affinity and ionizing potential are the values obtained by the measurement of the above-mentioned measurement method.

For such a smoothing layer, a material having the charge transporting property, that is, a material having the hole transporting property or a material having the electron transporting property can be used preferably.

The material having the hole transporting property used in the present invention is not particularly limited as long as it is a material capable of smoothly transporting the hole injected from the anode into the light emitting layer at the time of providing an organic EL element using a substrate for an organic EL element of the present invention. In particular, one having a high hole mobility is preferable. For example, a polyparaphenylene vinylene, a polythiophene, a polyparaphenylene, a polysilane, a polyacetylene, a polyvinyl carbazol, a polyfluorene, a polyquinoxaline, a polyaniline, a polypyrrole, and a conductive polymer such as their derivatives, their copolymers, or the like can be presented. Moreover, for example, aryl amines such as a triphenyl amine derivative; phthalocyanines; oxides such as a vanadium oxide, a molybdenum oxide, a ruthenium oxide, an aluminum oxide, and a titanium oxide; an amorphous carbon; or the like can be used as well.

Among these example, a polyfluorene derivative, a triphenyl amine derivative, and their copolymers, or a poly(3,4-ethylene dioxythiophene)-polystyrene sulfonic acid (PEDOT-PSS) can be used preferably.

Moreover, as the material having the hole transporting property, for example, ADS259BE produced by American Dye Source, Inc., or the like can be used as well. The material also has the electron blocking property. Moreover, among these examples, those having the weight average molecular weight of 10,000 or more based on the polystyrene are preferable. The weight average molecular weight can be measured by the gel permeation chromatography (GPC) method.

Moreover, the material having the electron transporting property used in the present invention is not particularly limited as long as it is a material capable of smoothly transporting the electron injected from the cathode into the light emitting layer at the time of providing an organic EL element using a substrate for an organic EL element of the present invention. In particular, one having a high electron mobility is preferable. For example, oxadiazols; triazols; phenanthrolines such as a vasocuproine and a vasophenanthroline; aluminum complexes such as a tris(8-quinolinolato) aluminum complex (Alq₃); or the like can be presented.

Moreover, a metal doped organic layer prepared by doping an alkaline metal or an alkaline earth metal into an electron transporting organic material can also be used as the smoothing layer. As the electron transporting organic material used at the time, phenanthrolines such as a vasocuproine and a vasophehanthroline, or the like can be presented. As the alkaline metal or the alkaline earth metal to be doped, Li, Cs, Ba, Sr, or the like can be presented.

The thickness of the above-mentioned smoothing layer is not particularly limited as long as it is a thickness capable of improving the surface state of the photocatalyst containing layer. Specifically, although it differs depending on the kind of the above-mentioned material having the charge transporting property, it is preferably about 20 nm to 100 nm; more preferably in a range of 30 nm to 80 nm; and most preferably in a range of 30 nm to 50 nm. If the smoothing layer is too thin, it is difficult to smooth the surface of the photocatalyst containing layer. Moreover, if the smoothing layer is too thick, transportation of the holes or the electrons may be inhibited.

According to the present invention, the smoothing layer can be formed by preparing a smoothing layer forming coating solution with the above-mentioned material having the charge transporting property dissolved or dispersed in a solvent, and coating the smoothing layer forming coating solution on the photocatalyst containing layer.

The method for coating the smoothing layer forming coating solution is not particularly limited as long as it is a method capable of evenly forming the smoothing layer. For example, a spray coating method, a dip coating method, a roll coating method, a bead coating method, a blade coating method, a spin coating method, a micro gravure coating method, a gravure coating method, bar coating method, a wire bar coating method, a casting method, an ink jet method, a LB method, a flexo printing method, an offset printing method, a screen printing method, or the like can be presented.

At the time, in the case the photocatalyst containing layer to be described later has the wettability change by the function of the photocatalyst accompanied by the energy irradiation, the smoothing layer can be formed in a pattern, utilizing the wettability change in the surface of the photocatalyst containing layer.

On the other hand, in the case of patterning the smoothing layer when the photocatalyst containing layer to be described later does not have the wettability change by the function of the photocatalyst accompanied by the energy irradiation, since the patterning cannot be carried out by utilizing the photocatalyst containing layer, the smoothing layer can be formed on the photocatalyst containing layer using for example the ink jet method, or the like.

Furthermore, after coating the above-mentioned smoothing layer forming coating solution, in general, a drying operation is carried out. The drying method is not particularly limited as long as it is a method capable of forming an even film. For example, a method of using a hot plate, an infrared ray heater, or an oven can be presented.

2. Photocatalyst Containing Layer

The photocatalyst containing layer used in the present invention is not particularly limited as long as it contains a photocatalyst, and it preferably has a charge injecting function of stably injecting the holes or the electrons from the electrode layer to the smoothing layer. Thereby, in the case of providing an organic EL element using a substrate for an organic EL element of the present invention, the light emitting efficiency can be improved.

As the photocatalyst used in the present invention, for example, metal oxides known as a photo semiconductor such as a titanium oxide (TiO₂), a zinc oxide (ZnO), a tin oxide (SnO₂), a strontium titanate (SrTiO₃), a tungsten oxide (WO₃), a bismuth oxide (Bi₂O₃), an iron oxide (Fe₂O₃) can be presented. One or more of these examples can be mixed for use. Among these examples, it is particularly preferable to use a titanium oxide. The titanium oxide is advantageous in that it has a high band gap energy; it is chemically stable; it is not hazardous; and it is easily accessible.

As the titanium oxide, either of the anatase type and the rutile type can be used. In particular, it is preferable to use an anatase type titanium oxide. The anatase type titanium oxide has the exciting wavelength at 380 nm or less.

As the anatase type titanium oxide, specifically, a hydrochloric acid peptisation type anatase type titania sol (produced by ISHIHARA SANGYO KAISHA, LTD., STS-02, average particle size 7 nm), a nitric acid peptisation type anatase type titania sol (produced by NISSAN CHEMICAL INDUSTRIES, LTD., TA-15, average particle size 12 nm), an anatase type titania sol (produced by TAYCA Co., Ltd., TK-420, average particle size 6 nm), a titanium oxide coating agent can be presented.

The content of the photocatalyst in the photocatalyst containing layer is not particularly limited as long as it is of an amount not to hinder the movement of the holes or the electrons. As it will be described later, since the photocatalyst containing layer preferably has the wettability change by the function of the photocatalyst accompanied by the energy irradiation, an amount capable of changing the wettability of the photocatalyst containing layer is preferable. Specifically, it can be set at about 1 to 90% by weight, and it is preferably in a range of 50 to 80% by weight.

The content, the crystal type, the crystallization degree, or the like of the titanium oxide in the photocatalyst containing layer can be confirmed by using the X ray photoelectron spectrometry, the Rutherford back scattering spectrometry, the nuclear magnetic resonance spectrometry, or the mass spectrometry, or a combination of these methods.

Moreover, the photocatalyst containing layer used in the present invention may either have the wettability change by the function of the photocatalyst accompanied by the energy irradiation or not have the wettability change. In particular, it is preferable to have the wettability change. By directing an energy in a pattern to the photocatalyst containing layer for exciting the photocatalyst in the photocatalyst containing layer, the wettability of the photocatalyst containing layer can be changed so that the energy irradiated portion can be lyophilic and the unirradiated portion can be liquid repellent. By utilizing the wettability difference, the smoothing layer, the light emitting layer, or the like can be patterned easily.

Hereinafter, the case of the photocatalyst containing layer not to have the wettability change by the function of the photocatalyst accompanied by the energy irradiation and the case to have the wettability change by the function of the photocatalyst accompanied by the energy irradiation will be explained separately.

(1) Case not to have the Wettability Change

In the case the photocatalyst containing layer used in the present invention does not have the wettability change by the function of the photocatalyst accompanied by the energy irradiation, the photocatalyst containing layer may comprise a binder. Thereby, the film formation of the photocatalyst containing layer can be facilitated. The binder used in the present invention is not particularly limited as long as its main skeleton has a high bonding energy not to be decomposed by the photo excitation of the photocatalyst, and for example, an alkyl silicate can be used. As the alkyl silicate, a compound represented by the general formula: SiₙOₙ₋₁ (OR)₂ₙ₊₂ (wherein Si is a silicon, O is an oxygen and R is an alkyl group) can be presented. Here, those having n in a range of 1 to 6, and R as an alkyl group having 1 to 4 carbon atoms are preferable in terms of having a high silicon ratio.

The thickness of the above-mentioned photocatalyst containing layer is not particularly limited as long as it is a thickness not to disturb the movement of the holes or the electrons. Specifically, it is preferably 10 nm to 500 nm; more preferably 10 nm to 200 nm; and particularly preferably in a range of 10 nm to 100 nm. If the photocatalyst containing layer is too thin, even film formation is difficult. On the other hand, if the photocatalyst containing layer is too thick, the movement of the holes or the electrons may be inhibited.

(2) Case to have the Wettability Change

In the case the photocatalyst containing layer used in the present invention has the wettability change by the function of the photocatalyst accompanied by the energy irradiation, the photocatalyst containing layer is not particularly limited as long as it has the wettability change by the function of the photocatalyst accompanied by the energy irradiation. As a preferable embodiment, the case wherein a photocatalyst containing layer is a photocatalyst containing wettability changeable layer containing a photocatalyst so as to have the wettability change by the function of the photocatalyst accompanied by the energy irradiation (first embodiment), and the case wherein a photocatalyst containing layer comprising a photocatalyst processing layer containing a photocatalyst and a wettability changeable layer having the wettability change by the function of the photocatalyst accompanied by the energy irradiation (second embodiment) can be presented.

Hereinafter each embodiment will be explained.

### (i) First Embodiment

The first embodiment of the photocatalyst containing layer in the present invention is a photocatalyst containing wettability changeable layer containing a photocatalyst so as to have the wettability change by the function of the photocatalyst accompanied by the energy irradiation. Since the photocatalyst containing wettability changeable layer has the wettability change by the function of the photocatalyst contained in the photocatalyst containing wettability changeable layer itself, it is advantageous in that the wettability changeable pattern can be formed efficiently.

The photocatalyst containing wettability changeable layer of this embodiment is not particularly limited as long as it contains the photocatalyst so as to have the wettability change by the function of the photocatalyst accompanied by the energy irradiation. In general, it comprises a photocatalyst and a binder having the wettability change by the function of the photocatalyst.

The binder used in this embodiment preferably has a high bonding energy not to be decomposed by the photo excitation of the photocatalyst, and an organic substituent to be decomposed by the function of the photocatalyst. For example, (1) an organopolysiloxane to perform a high strength by hydrolysis or polycondensation of a chloro or alkoxy silane, or the like by the sol gel reaction, or the like; (2) an organopolysiloxane produced by cross-linking a reactive silicone having the excellent water repellency and oil repellency; or the like can be presented.

In the case (1), it is preferably an organopolysiloxane as a hydrolyzed condensation product or a co-hydrolyzed condensation product of one or two or more kinds of silicon compounds represented by the general formula:
YₙSiX₍₄₋ₙ₎

(Here, Y is an alkyl group, a fluoroalkyl group, a vinyl group, an amino group, a phenyl group, or an epoxy group; and X is an alkoxy group, an acetyl group or a halogen. n is an integer from 0 to 3). Here, the number of atoms of the group represented by Y is preferably in a range of 1 to 20. Moreover, the alkoxy group represented by X is preferably a methoxy group, an ethoxy group, a propoxy group, or a butoxy group. Specifically, for example, those disclosed in the official gazette of the JP-A No. 2000-249821 can be used.

Moreover, an organopolysiloxane containing a fluoro alkyl group can be used preferably. Specifically, an organopolysiloxane disclosed in the official gazette of the JP-A No. 2003-195029 can be used.

It can be confirmed that the organopolysiloxane having the fluoroalkyl group is contained in the photocatalyst containing wettability changeable layer by the X ray photoelectron spectrometry, the Rutherford back scattering spectrometry, the nuclear magnetic resonance spectrometry, the infrared spectroscopy, the mass spectrometry or a combination of thereof.

Moreover, as the reactive silicone (2), compounds having a skeleton represented by the following general formula can be presented.

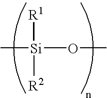

n is an integer of 2 or more; R¹, R² each are a substituted or non substituted alkyl, alkenyl, aryl or cyanoalkyl group having 1 to 10 carbon atoms; and 40% or less of the entirety based on the mole ratio is preferably a vinyl, a phenyl, or a halogenated phenyl. Moreover, those having R¹, R² as a methyl group are preferable since the surface energy becomes the smallest, and it is preferable that a methyl group accounts for 60% or more based on the mole ratio. Moreover, at least one reactive group such as a hydroxyl group is provided in a molecular chain at the chain end or the side chain.

Moreover, together with the above-mentioned organopolysiloxane, a stable organosilicon compound with no cross-linking reaction such as a dimethylpolysiloxane may be mixed.

In the present embodiment, a surfactant which can be decomposed by the function of the photocatalyst and has a function of changing the wettability by the decomposition can be included in the photocatalyst containing wettability changeable layer. Specifically, hydrocarbons of the respective series of NIKKO L BL, BC, BO, and BB manufactured by Nikko Chemicals Co., Ltd.; and fluorine base or silicone base nonionic surfactants such as ZONYL FSN and FSO manufacture by Du Pont Kabushiki Kaisha, Surflon S-141 and 145 manufactured by ASAHI GLASS CO., LTD., Megaface F-141 and 144 manufactured by DAINIPPON INK AND CHEMICALS, Inc., FTERGENT F-200 and F251manufactured by NEOS, UNIDYNE DS-401 and 402 manufactured by DAIKIN INDUSTRIES, Ltd., and Fluorad FC-170 and 176 manufactured by 3M can be cited. Cationic surfactants, anionic surfactants and amphoteric surfactants also can be used.

Other than the surfactants, oligomers and polymers such as polyvinyl alcohol, unsaturated polyester, acrylic resin, polyethylene, diallyl phthalate, ethylene propylene diene monomer, epoxy resin, phenol resin, polyurethane, melamine resin, polycarbonate, polyvinyl chloride, polyamide, polyimide, styrene-butadiene rubber, chloroprene rubber, polypropylene, polybutylene, polystyrene, polyvinyl acetate, polyester, polybutadiene, polybenzimidazole, polyacrylonitrile, epichlorohydrine, polysulfide, polyisoprene and the like can be included in the photocatalyst containing wettability changeable layer.

Furthermore, the photocatalyst containing wettability changeable layer may contain a sensitizing pigment as a component for sensitizing the photo activity of the photocatalyst. By adding such a sensitizing pigment, the wettability can be changed by a low exposing amount, or the wettability can be changed by exposing with a different wavelength.

The thickness of the above-mentioned photocatalyst containing wettability changeable layer is not particularly limited as long as it is a thickness capable of changing the wettability of the surface and allowing the movement of the holes or the electrons. Specifically, it is preferably 10 nm to 500 nm; more preferably 10 nm to 200 nm; and particularly preferably in a range of 10 nm to 100 nm. If the photocatalyst containing wettability changeable layer is too thin, the wettability change may not appear clearly. On the other hand, if the photocatalyst containing wettability changeable layer is too thick, the movement of the holes or the electrons may be inhibited.

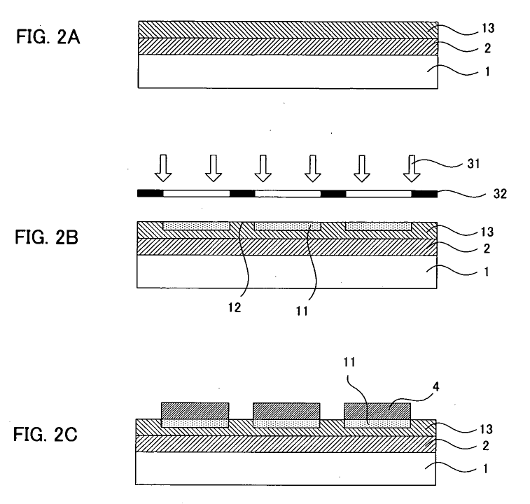

Next, a method for changing the wettability of the photocatalyst containing wettability changeable layer surface will be explained with reference to FIGS. 2A to 2C.

First, by coating a photocatalyst containing wettability changeable layer forming coating solution on a base material 1 with an electrode layer 2 formed, a photocatalyst containing wettability changeable layer 13 is formed (FIG. 2A). Next, by directing an energy 31 in a pattern via a photo mask 32 to the photocatalyst containing wettability changeable layer 13, the wettability of the photocatalyst containing wettability changeable layer 13 surface is changed so as to form a wettability changeable pattern comprising a lyophilic region 11 and a liquid repellent region 12 (FIG. 2B).

In the case of using such a photocatalyst containing wettability changeable layer, as shown in FIG. 2C, a smoothing layer 4 can be formed only in the lyophilic region 11 of the photocatalyst containing wettability changeable layer 13 surface.

A solvent used for the photocatalyst containing wettability changeable layer forming coating solution is not particularly limited as long as it can be mixed with the above-mentioned photocatalyst for dissolving the above-mentioned binder, or the like without influencing the film forming characteristic and the patterning characteristic by the cloudiness or the other phenomena. As such a solvent, alcohols such as a methanol, an ethanol, an isopropanol and a butanol, an acetone, an acetonitrile, an ethylene glycol monomethyl ether, an ethylene glycol dimethyl ether, an ethylene glycol monoethyl ether, an ethylene glycol monoethyl ether acetate, a diethyl glycol monomethyl ether, a diethyl glycol monoethyl ether, a diethyl glycol monoethyl ether acetate, a propylene glycol monomethyl ether, a propylene glycol monoethyl ether, a propylene glycol monomethyl ether acetate, a methyl acetate, an ethyl acetate, a butyl acetate, a toluene, a xylene, a methyl lactate, an ethyl lactate, an ethyl pyruvate, a 3-methoxy methyl propionate, a 3-ethoxy ethyl propionate, a dimethyl formamide, a dimethyl sulfoxide, a dioxane, an ethylene glycol, a hexamethyl triamide phosphate, a pyridine, a tetrahydro furan, a N-methyl pyrolidinone or the like can be presented. These solvents may be used as a mixture of two or more kinds.

Moreover, as the coating method of the photocatalyst containing wettability changeable layer forming coating solution, for example, a spin coating method, an ink jet method, a casting method, a LB method, a dispenser method, a micro gravure coating method, a gravure coating method, a bar coating method, a roll coating method, a wire bar coating method, a dip coating method, a flexo printing method, an offset printing method, a screen printing method or the like can be presented.

After coating the photocatalyst containing wettability changeable layer forming coating solution, the base material will be dried. The drying method of the solution is not particularly limited as long as it is a method capable of coating an even layer. For example, a method of using a hot plate, an infrared ray heater, or an oven can be presented.

Although the action mechanism by the photocatalyst containing wettability changeable layer is not always clear, it is considered that the photocatalyst generates the oxidation reduction reaction by the energy irradiation so as to generate the active oxygen species such as the super oxide (O₂—) and a hydroxyl radical (.OH) so that the generated active oxygen species influence the chemical structure of the organic substance.

The energy irradiation (exposure) in the present invention is the concept including the irradiation of any energy line capable of exciting the photocatalyst. In addition to the ultraviolet ray, the visible light beam and the infrared ray, the electromagnetic waves and the radiations of a wavelength shorter or longer than the same are included as well.

The energy irradiation method is not particularly limited as long as it is a method capable of changing the wettability of the photocatalyst containing wettability changeable layer. Moreover, the energy irradiation may be carried out using a mask such as a photo mask, with a purposed pattern formed. Thereby, the energy irradiation in a purposed pattern can be enabled so that the wettability of the photocatalyst containing wettability changeable layer can be changed in a pattern. At the time, the kind of the mask to be used is not particularly limited as long as the energy irradiation in a purposed pattern can be enabled. It may be a photo mask or the like with a light shielding part formed in a energy transmittable material, or it may be a shadow mask or the like with a hole part formed in a purposed pattern. As a material for the mask, specifically, an inorganic substance such as a metal, a glass or a ceramic, or an organic substance such as a plastic or the like, can be cited.

Furthermore, in the case a light shielding part is formed on the base material to be used, the energy irradiation may be the entire surface exposure from the base material side, utilizing the light shielding part. Thereby, the energy can be directed only to the photocatalyst containing wettability changeable layer at a position without formation of the light shielding part so as to change the wettability of the photocatalyst containing wettability changeable layer. In this case, since it is unnecessary to use the mask or to irradiate a laser ray for drawing irradiation, the positioning, expensive device or the like for drawing irradiation is not required. Thus it is advantageous.

For energy irradiation, ultraviolet ray is normally used. Specifically, a wavelength of the ultraviolet ray is set in a range of 400 nm or less, preferably in a range of 150 nm to 380 nm. This is because, as mentioned above, a preferable photocatalyst used in the photocatalyst containing wettability changeable layer is the titanium oxide and it is preferable to use the light of the above wavelength as energy to activate the photocatalyst action with the titanium oxide.

As for the light source that can be used for such an energy irradiation, various light sources such as a mercury lamp, a metal halide lamp, a xenon lamp, and an excimer lamp can be cited. The energy can be irradiated using a laser such as an excimer or YAG. By using the laser to irradiate the energy, the positioning of the photomask mentioned above or the like becomes unnecessary, thus the wettability of the photocatalyst containing wettability changeable layer can be changed highly precisely without forming the light shielding part on the base material.

Moreover, in the case an anatase type titanium oxide is used as the photocatalyst, since the excitation wavelength of the anatase type titanium oxide is 380 nm or less, the energy irradiation can be carried out with an ultraviolet ray. For the light source which radiates such ultraviolet ray, a high pressure mercury lamp (154, 313, 365, 405, 436, 546, 577 nm), a superhigh pressure mercury lamp (250 to 600 nm), a metal halide lamp (250 to 600 nm), a xenon lamp (300 to 1100 nm), an excimer laser, or other ultraviolet ray light sources can be used.

The energy irradiation amount at the time of the energy irradiation is an irradiation amount necessary for changing the wettability of the photocatalyst containing wettability changeable layer by the function of the photocatalyst in the photocatalyst containing wettability changeable layer.

The photocatalyst containing wettability changeable layer used in the present invention has the wettability change by the function of the photocatalyst accompanied by the energy irradiation so that the contact angle with respect to a liquid is changed to the lower direction. By the energy irradiation in a pattern to the photocatalyst containing wettability changeable layer, a wettability changeable pattern comprising the lyophilic region in the portion with the energy irradiation and the liquid repellent region of the energy unirradiated portion can be formed.

Here, the lyophilic region is a region having a small contact angle with respect to a liquid, and it refers to a region having a good wettability with respect to a liquid. Moreover, the liquid repellent region is a region having a large contact angle with respect to a liquid, and it denotes a region having a poor wettability with respect to a liquid.

It is preferable that the contact angles with respect to a liquid in the lyophilic region formed by the energy irradiation and the liquid repellent region without the energy irradiation differ by at least 1° or more; preferably 5° or more; and particularly preferably 10° or more.

Moreover, about the photocatalyst containing wettability changeable layer, in the region irradiated with energy, that is, in the lyophilic region, the contact angle with respect to a liquid is lowered by the energy irradiation. It is preferable that the contact angle with a liquid having a surface tension of 40 mN/m is 9° or less. More preferably, the contact angle with a liquid having a surface tension of 50 mN/m is 10° or less; and even more preferably the contact angle with a liquid having a surface tension of 60 mN/m is 10° or less for the following reason: in the case the contact angle in the portion with the energy irradiation, that is, the lyophilic region with respect to the liquid is high, spreading of the liquid may be poor in this portion so that a problem of lacking of the smoothing layer or the light emitting layer or the like may be generated.

On the other hand, about the photocatalyst containing wettability changeable layer, in the region not irradiated with energy, that is, in the liquid repellent region, preferably, the contact angle with a liquid having a surface tension of 40 mN/m is 10° or more; more preferably, the contact angle with a liquid having a surface tension of 30 mN/m is 10° or more; and even more preferably the contact angle with a liquid having a surface tension of 20 mN/m is 10° or more. Since the portion without the energy irradiation is the portion required to have the liquid repellency, in the case the contact angle with respect to a liquid is small, due to the insufficient liquid repellency, the patterning characteristic may be lowered.

The contact angle with respect to a liquid here is obtained from the results or a graph of the results of measuring (30 seconds after of dropping liquid droplets from a micro syringe) the contact angle with respect to liquids having various surface tensions using a contact angle measuring device (CA-Z type manufactured by Kyowa Interface Science, Co., Ltd). Moreover, at the time of the measurement, as the liquids having the various surface tensions, wetting index standard solution manufactured by JUNSEI CHEMICAL CO., LTD. were used.

### (ii) Second Embodiment

The second embodiment of the photocatalyst containing layer in the present invention comprises a photocatalyst processing layer containing a photocatalyst and a wettability changeable layer having the wettability change by the function of the photocatalyst accompanied by the energy irradiation. Since the photocatalyst containing layer having the photocatalyst processing layer and the wettability changeable layer has layers separated per function, it is advantageous in that the combination of the layer configuration and the material, or the like can easily be changed.

Hereinafter, the photocatalyst processing layer and the wettability changeable layer will be explained.

(Photocatalyst Processing Layer)

The photocatalyst processing layer used in this embodiment is not particularly limited as long as it contains the photocatalyst so that the photocatalyst in the photocatalyst processing layer changes the wettability of the laminated wettability changeable layer.

Moreover, the photocatalyst processing layer may further contain a binder. Thereby, the film formation can be facilitated. The binder used in this embodiment is not particularly limited as long as its main skeleton has a high bonding energy not to be decomposed by the photoexcitation of the photocatalyst. Either of the binders used for the photocatalyst containing layer without changing the wettability mentioned above, or the binders mentioned in the above-mentioned first embodiment can be used.

Furthermore, the wettability of the photocatalyst processing layer surface may either by lyophilic or liquid repellent.

The thickness of the above-mentioned photocatalyst processing layer is not particularly limited as long as it is a thickness not to disturb the movement of the holes or the electrons. Specifically, it is preferably 10 nm to 500 nm; more preferably 10 nm to 200 nm; and particularly preferably in a range of 10 nm to 100 nm. If the photocatalyst processing layer is too thin, the wettability of the wettability changeable layer may hardly be changed. On the other hand, if the photocatalyst containing layer is too thick, the movement of the holes or the electrons may be inhibited.

(Wettability Changeable Layer)

The wettability changeable layer used in this embodiment is not particularly limited as long as it has the wettability change by the function of the photocatalyst. In general, it contains a binder to have the wettability change by the function of the photocatalyst. Since the binders are the same as those mentioned in the above-mentioned first embodiment, description will not be repeated here.

Moreover, the wettability changeable layer may contain the same surfactants, additives, or the like mentioned in the above-mentioned first embodiment.

The thickness of the above-mentioned wettability changeable layer is not particularly limited as long as it is a thickness capable of forming the wettability changeable pattern without inhibiting the movement of the holes or the electrons. Specifically, it is preferably 0.5 nm to 20 nm, and more preferably 0.5 nm to 10 nm. If the wettability changeable layer is too thin, the wettability change may not appear clearly. On the other hand, if the wettability changeable layer is too thick, the movement of the holes or the electrons may be inhibited.

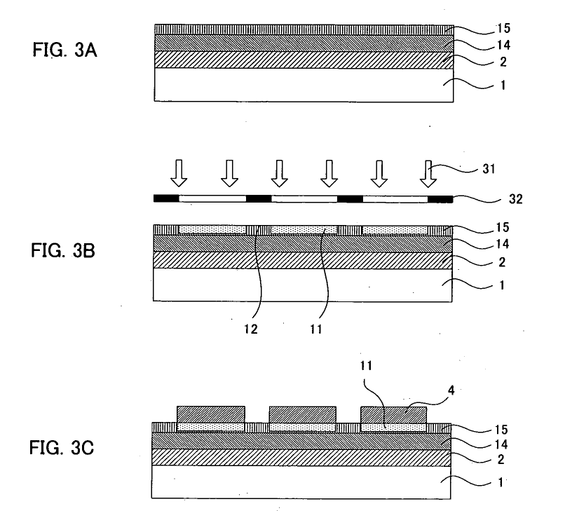

Next, a method for changing the wettability of the wettability changeable layer surface will be explained with reference to FIGS. 3A to 3C.

First, by coating a photocatalyst processing layer forming coating solution on a base material 1 with an electrode layer 2 formed, a photocatalyst processing layer 14 is formed. Then, by coating a wettability changeable layer forming coating solution on the photocatalyst processing layer 14, a wettability changeable layer 15 is formed (FIG. 3A). Next, by directing an energy 31 in a pattern via a photo mask 32 to the wettability changeable layer 15, the wettability of the wettability changeable layer 15 surface is changed so as to form a wettability changeable pattern having a lyophilic region 11 and a liquid repellent region 12 (FIG. 3B).

In the case of using such a wettability changeable layer, as shown in FIG. 3C, a smoothing layer 4 can be formed only in the lyophilic region 11 of the photocatalyst containing wettability changeable layer 15 surface.

Since the other points of the method for changing the wettability are the same as those mentioned in the above-mentioned first embodiment, description will not be repeated here.

3. Electrode Layer

The electrode layer used in the present invention may either be an anode or a cathode. Depending on whether the electrode layer is an anode or a cathode, the kind of the charge transporting property of the above-mentioned smoothing layer can be selected appropriately.

In the case the substrate for an organic EL element of the present invention is used for an organic EL element, when the substrate for an organic EL element side is the light beam taking out surface, the electrode layer needs to be transparent. On the other hand, when the substrate for an organic EL element side is not the light beam taking out side, the electrode layer may either be transparent or not.

As the anode, it is preferable to use a conductive material having a large work function for facilitating the hole injection. Specifically, an indium tin oxide (ITO), an indium oxide, a gold, and the like can be presented.

For the cathode, it is preferable to use a conductive material having a small work function for facilitating the electron injection. For example, magnesium alloys such as MgAg; aluminum alloys such as AlLi, AlCa, and AlMg; alkaline metals and alkaline earth metals such as Li and Ca; alloys of the alkaline metals and the alkaline earth metals; or the like can be presented.

Moreover, it is preferable that the electrode layer has a small resistance. In general, a metal material is used, however, an organic compound or an inorganic compound may be used as well.

Furthermore, the electrode layer may either be formed on the entire surface on the base material, or formed in a pattern.

As for the method of forming the electrode layer, a conventional forming method of the electrode can be employed. For example, physical vapor deposition (PVD) method such as vacuum deposition method, sputtering method, or ion plating method, or chemical vapor deposition (CVD) method can be cited. For a patterning method of the electrode layer, there is no particular limitation imposed as long as a desired pattern can be formed precisely. Photolithography method or the like can be cited as a specific example.

4. Base Material

The base material used in the present invention is not particularly limited as long as it supports the above-mentioned electrode layer, photocatalyst containing layer, smoothing layer, or the like and it has a predetermined strength. In the present invention, in the case the above-mentioned electrode layer has a predetermined strength, the electrode layer may serve also as the base material, however, in general, the electrode layer is formed on a base material having a predetermined strength.

Moreover, in the case the substrate for an organic EL element of the present invention is used for an organic EL element, when the substrate for an organic EL element side is the light beam taking out side, the base material needs to be transparent. As such a base material, for example, glass substrates such as a soda lime glass, an alkaline glass, a lead alkaline glass, a borosilicate glass, an alumino silicate glass, and a silica glass; a resin substrate capable of being shaped as a film; or the like can be used.

B. Organic EL Element

Next, an organic EL element of the present invention will be explained.

The organic EL element of the present invention comprises the above-mentioned substrate for an organic EL element; an organic EL layer having at least a light emitting layer, formed on the smoothing layer of the above-mentioned substrate for an organic EL element; and a counter electrode layer formed on the above-mentioned organic EL layer.

The organic EL element of the present invention will be |explained with reference to the drawings.

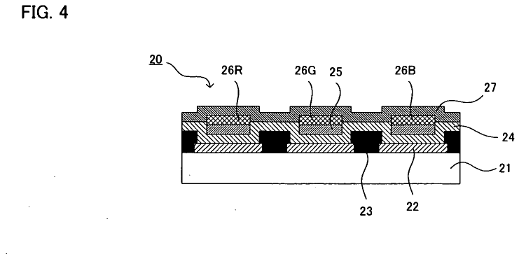

FIG. 4 is a schematic cross-sectional view showing an example of an organic EL element of the present invention. As shown in FIG. 4, according to an organic EL element 20 of the present invention, an electrode layer 22 is formed in a pattern on a base material 21; an insulation layer 23 is formed between the electrode layers 22; and a photocatalyst containing layer 24 is formed on the electrode layer 22 and the insulation layer 23. A smoothing layer 25 is formed in a pattern on the photocatalyst containing layer 24, and a light emitting layer (a red light emitting layer 26R, a green light emitting layer 26G and a blue light emitting layer 26B) is formed on the smoothing layer 25. Furthermore, a counter electrode layer 27 is formed on the light emitting layers 26R, 26G and 26B.

In the present invention, since the above-mentioned substrate for an organic EL element is used so that the surface state of the photocatalyst containing layer is improved and the light emitting layer is formed on the smoothing layer having the excellent surface smoothness, the barrier at the interfaces of the respective layers from the photocatalyst containing layer to the light emitting layer can be reduced. Moreover, since the smoothing layer has the charge transporting property, the charges injected from the electrode layer can be transported smoothly to the light emitting layer. Therefore, according to the present invention, the light emission characteristic of the organic EL element can be improved.

Moreover, in the case the photocatalyst containing layer has the wettability change by the function of the photocatalyst accompanied by the energy irradiation, the smoothing layer, the light emitting layer, or the like can be patterned easily.

Since the base material, the electrode layer, the photocatalyst containing layer and the smoothing layer are the same as those mentioned in the above-mentioned column of “A. Substrate for an organic EL element”, respectively, explanation will not be repeated here. Hereinafter, the organic EL layer and the counter electrode layer in the organic EL element of the present invention will be explained.

1. Organic EL Layer

The organic EL layer used in the present invention has one layer or a plurality of organic layers including at least a light emitting layer. That is, the organic EL layer is a layer including at least a light emitting layer, with the layer configuration of one organic layer or more. In general, in the case the organic EL layer is formed by the wet process by coating, since the lamination of a large number of layers is difficult according to the relationship with the solvent, it is formed as one layer or two layers of organic layers in many cases. However, it is also possible to provide a larger number of layers by skillfully using the organic material or employing the vacuum deposition method in a combination.

As the organic layers formed in the organic EL layer in addition to the light emitting layer, a charge injecting layer such as a hole injecting layer and an electron injecting layer can be presented. Furthermore, as the other organic layers, a charge transporting layer such as a hole transporting layer for transporting the hole to the light emitting layer, and an electron transporting layer for transporting the electron to the light emitting layer can be presented. In general, these layers can be provided integrally with the charge injecting layer by providing the charge transporting function to the above-mentioned charge injecting layer. Additionally, as the organic layer formed in the organic EL layer, a layer for preventing penetration of the hole or the electron for improving the re-bonding efficiency such as a carrier block layer can be presented.

In the present invention, since the smoothing layer of the substrate for an organic EL element has the charge transporting property and it is preferable that the photocatalyst containing layer has the charge injecting function, the charge injecting layer, the charge transporting layer, or the like may not be formed on the side to be contacted with the smoothing layer as the organic EL layer. On the other hand, it is preferable that the charge injecting layer, the charge transporting layer, or the like are formed as the organic EL layer on the side to be contacted with the counter electrode layer. Thereby, the light emitting efficiency can be improved.

Hereinafter, each configuration of such an organic EL layer will be explained.

(1) Light Emitting Layer

As the light emitting material used for the light emitting layer as the essential configuration of the organic EL layer in the present invention, for example, a light emitting material such as a pigment based light emitting material, a metal complex based light emitting material, and a polymer based light emitting material can be used.

As the pigment based light emitting material, for example, a cyclopentadiene derivative, a tetraphenyl butadiene derivative, a triphenyl amine derivative, an oxadiazol derivative, a pyrazoloquinoline derivative, a distylyl benzene derivative, a distylyl arylene derivative, a silol derivative, a thiophene ring compound, a pyridine ring compound, a perynon derivative, a perylene derivative, an oligothiophene derivative, a triphmanyl amine derivative, an oxadiazol dimer, a pyrazoline dimer, or the like can be presented.

Moreover, as the metal complex based light emitting material, for example, metal complexes having Al, Zn, Be, or the like, or a rare earth metal such as Tb, Eu, Dy, or the like as the central metal, and an oxadiazol, a thiadiazol, a phenyl pyridine, a phenyl benzoimidazol, a quinoline structure, or the like as the ligand, such as an aluminum quinolinol complex, a benzoquinolinol beryllium complex, a benzoxazol zinc complex, a benzothiazol zinc complex, an azomethyl zinc complex, a porphiline zinc complex, an europium complex, or the like can be presented.

Furthermore, as the polymer based light emitting material, for example, a polyparaphenylene vinylene derivative, a polythiophene derivative, a polyparaphenylene derivative, a polysilane derivative, a polyacetylene derivative, a polyvinyl carbazol, a polyfluolene derivative, a polyquinoxaline derivative, a polymer thereof, or the like can be presented.

For the purpose of improving the light emitting efficiency, changing the light emitting wavelength, or the like, a doping agent may be added into the above-mentioned light emitting layer. As such a doping agent, for example, a perylene derivative, a coumarin derivative, a rubrene derivative, a quinacrydone derivative, a squalium derivative, a porphiline derivative, a styryl based pigment, a tetracene derivative, a pyrazoline derivative, a decacyclene, a phenoxazone, a quinoxaline derivative, a carbazol derivative, and a fluolene derivative can be presented.

The thickness of the light emitting layer is not particularly limited as long as it is a thickness capable of providing the field for re-bonding of the electron and the hole so as to provide the light emitting function. For example, it can be about 10 nm to 500 nm.

In the present invention, by coating a light emitting layer forming coating solution with the above-mentioned light emitting material dissolved or dispersed in a solvent, the light emitting layer can be formed.

The solvent used for the light emitting layer forming coating solution is not particularly limited as long as it can dissolve or disperse the above-mentioned light emitting material. Specifically, a chloroform, a methylene chloride, a dichloro ethane, a tetrahydro furan, a toluene, a xylene, or the like can be presented.

Moreover, the method of coating the light emitting layer forming coating solution is not particularly limited as long as it is a method capable of forming a light emitting layer evenly and highly precisely. As such a coating method, for example, a dip coating method, a roll coating method, a blade coating method, a spin coating method, a micro gravure coating method, a gravure coating method, bar coating method, a wire bar coating method, a casting method, an ink jet method, a LB method, a flexo printing method, an offset printing method, a screen printing method, or the like can be presented.

At the time, in the case the photocatalyst containing layer has the wettability change by the function of the photocatalyst accompanied by the energy irradiation, the light emitting layer can be patterned by utilizing the wettability difference in the photocatalyst containing layer surface.

On the other hand, when patterning the light emitting layer in the case the photocatalyst containing layer does not have the wettability change by the function of the photocatalyst accompanied by the energy irradiation, since the patterning operation cannot be carried out by utilizing the photocatalyst containing layer, the light emitting layer may be formed on the smoothing layer using for example the ink jet method, or the like.

(2) Charge Injecting and Transporting Layer

In the present invention, a charge injecting and transporting layer may be formed between the counter electrode layer and the light emitting layer. The “charge injecting and transporting layer” here means one having at least one of a charge injecting function of stably injecting the charge from the counter electrode layer to the light emitting layer, and a charge transporting function of transporting the charge injected from the counter electrode layer smoothly. By providing such a charge injecting and transporting layer, since the charge injection to the light emitting layer can be stabilized or the charge transportation can be carried out smoothly, the light emitting efficiency can be improved.

As such a charge injecting and transporting layer, there are a hole injecting and transporting layer for transporting the hole injected from the anode into the light emitting layer, and an electron injecting and transporting layer for transporting the electron injected from the cathode into the light emitting layer. Hereinafter, the hole injecting and transporting layer and the electron injecting and transporting layer will be explained.

(i) Hole Injecting and Transporting Layer

The hole injection and transporting layer used in the present invention may be one of the hole injecting layer for injecting the hole into the light emitting layer or the hole transporting layer for transporting the hole, a lamination of the hole injecting layer and the hole transporting layer, or a single layer having the both functions of the hole injecting function and the hole transporting function.

The material used for the hole injecting and transporting layer is not particularly limited as long as it is a material capable of stably transporting the hole injected from the anode into the light emitting layer. For example, in addition to the above-mentioned light emitting materials, aryl amines; phthalocyanines; oxides such as a vanadium oxide, a molybdenum oxide, a ruthenium oxide, an aluminum oxide, and a titanium oxide; an amorphous carbon; conductive polymers such as a polyaniline, a polythiophene, a polyphenylene vinylene, and a derivative thereof; or the like can be used. Specifically, as the aryl amines, a bis(N-(1-naphthyl-N-phenyl) benzidine (α-NPD), a 4,4,4-tris(3-methyl phenyl phenyl amino)triphenyl amine (MTDATA), or the like can be presented; and as the polythiophene derivatives, a poly (3,4-ethylene dioxythiophene)-polystyrene sulfonic acid (PEDOT-PSS), or the like can be presented.

Moreover, the thickness of the hole injecting and transporting layer is not particularly limited as long as it is a thickness capable of sufficiently performing the function of injecting the hole from the anode and transporting the hole to the light emitting layer. Specifically, it is in a range of 0.5 nm to 1,000 nm, in particular it is preferably in a range of 10 nm to 500 nm.

(ii) Electron Injecting and Transporting Layer

The electron injecting and transporting layer used in the present invention may be one of the electron injecting layer for injecting the electron into the light emitting layer or the electron transporting layer for transporting the electron, a lamination of the electron injecting layer and the electron transporting layer, or a single layer having the both functions of the electron injecting function and the electron transporting function.

The material used for the electron injecting layer is not particularly limited as long as it is a material capable of stabilizing the electron injection into the light emitting layer. For example, in addition to the above-mentioned light emitting materials, alkaline metals such as an aluminum lithium alloy, a lithium and a cesium, and their alloys; alkaline metal halides such as a lithium fluoride, and a cesium fluoride; alkaline earth metals such as a strontium and a calcium; alkaline earth metal halides such as a magnesium fluoride, a strontium fluoride, a calcium fluoride and a barium fluoride; oxides such as a magnesium oxide, a strontium oxide and an aluminum oxide; or the like can be used. Moreover, a polymethyl methacrylate, a sodium polystyrene sulfonate, or the like can also be used.

The thickness of the electron injecting layer is not particularly limited as long as it is a thickness capable of sufficiently performing the electron injecting function.

Moreover, the material used for the electron transporting layer is not particularly limited as long as it is a material capable of transporting the electron injected from the electrode layer or the counter electrode layer into the light emitting layer. For example, oxadiazols, triazols, phenanthrolines such as a vasocuproine and a vasophenanthroline, aluminum complexes such as a tris (8-quinolinolato) aluminum complex (Alq₃), or the like can be presented.

The thickness of the electron transporting layer is not particularly limited as long as it is a thickness capable of sufficiently performing the electron transporting function.

Furthermore, as the electron injecting and transporting layer comprising a single layer having the both functions of the electron injecting function and the electron transporting function, a metal doped organic layer produced by doping an alkaline metal or an alkaline earth metal to an electron transporting organic material can be used. As the electron transporting organic material, for example, phenanthrolines such as a bathcuproine, a bathphenanthroline, or the like can be presented. As the doping alkali metal or alkali earth metal, Li, Cs, Ba, Sr or the like can be presented.

The thickness of the electron injecting and transporting layer comprising a single layer is not particularly limited as long as it is a thickness capable of sufficiently performing the electron injecting function and the electron transporting function.

2. Counter Electrode Layer

The counter electrode layer used in the present invention is formed on the above-mentioned organic EL layer, and to be the electrode on the opposite side of the electrode layer of the substrate for an organic EL element.

Since the other points of the counter electrode layer are the same as those mentioned in the item of the electrode layer of the above-mentioned “A. Substrate for an organic EL element”, explanation will be not repeated here.

3. Barrier

In the present invention, a barrier may be formed between the smoothing layers formed in a pattern and the organic EL layers. The barrier is particularly advantageous at the time of forming the light emitting layers to emit light beams of different colors.

As the material used for the barrier, for example, a photosensitive polyimide resin, an acrylic based resin, and additionally, a photo setting type resin, a thermosetting type resin, a water repellent resin, or the like can be presented.

4. Insulation Layer

In the present invention, an insulation layer may be formed between the electrode layers formed in a pattern. In general, the insulation layer is formed so as to cover the end part of the electrode layer. The insulation layer is provided for stopping the charge supply from the electrode layer to the organic EL layer. Moreover, the portion with the insulation layer formed can be a portion without the light emission.

For such an insulation layer, a photo setting resin such as a photosensitive polyimide resin and an acrylic based resin, a thermosetting resin, an inorganic material, or the like can be used.

Moreover, for a forming method of the insulation layer, those methods known in general, such as the photolithography method or the printing method, can be employed.

The present invention is not limited to the embodiments. The embodiments are merely examples, and any one having the substantially same configuration as the technological idea disclosed in the claims of the present invention and the same effects is included in the technological scope of the present invention.

### EXAMPLES

Hereinafter, the present invention will be explained specifically with reference to the examples and the comparative examples.

### Example 1

(Cleaning of an ITO Substrate)

An ITO substrate with an ITO film as a transparent electrode formed in a pattern on a 150 mm square glass substrate was washed by ultrasonic cleaning in an isopropyl alcohol, acetone solvent.

(Formation of a Photocatalyst Containing Layer)

By mixing the following components, a photocatalyst containing layer forming coating solution was prepared.

| | | |
|---|---|---|
| Titanium dioxide sol liquid (STS-01 produced | 3 | parts by weight |
| by ISHIHARA SANGYO KAISHA, LTD.) | | |
| Tetraethoxy silane | 1 | part by weight |
| 2 normal hydrochloric acid | 40 | parts by weight |
| Isopropyl alcohol | 75 | parts by weight |
| Fluoro alkoxy silane (MF-160E produced by | 7.5 | parts by weight |
| Tohkem Co., Ltd.) | | |

By coating the photocatalyst containing layer forming coating solution with a spin coater and carrying out a drying process at 150° C. for 10 minutes, a 60 nm film thickness transparent photocatalyst containing layer was formed. The photocatalyst containing layer has a 17 nm average surface roughness and a 130 nm maximum height difference.

By directing a light beam by a 70 mW/cm² illuminance for 50 seconds using a high pressure mercury lamp (254 nm, 365 nm) via a photo mask onto the photocatalyst containing layer, a wettability changeable pattern was formed.

(Formation of the Smoothing Layer)

A water dispersion of a PEDOT-PSS (poly(3,4-ethylene dioxythiophene)-polystyrene sulfonate) (product name; Baytron TP CH8000 produced by Bayer AG) was coated on the wettability changeable pattern by the spin coating method, and dried at 200° C. for 1 hour. Thereby, a 50 nm film thickness smoothing layer was formed in a pattern. By providing the smoothing layer, the average surface roughness became 7.9 nm, and the maximum height difference 50 nm.

(Formation of the Light Emitting Layer)

A toluene solution of a polyfluorene derivative (ADS132GE produced by American Dye Source, Inc.) was coated onto the smoothing layer by the spin coating method, and dried at 80° C. for 30 minutes, a 1,000 Å film thickness light emitting layer was formed in a pattern.

(Formation of the Metal Electrode)

Thereafter, a LiF film (film thickness 5 nm) and an Al film (film thickness 2,000 Å) were formed by the mask deposition method so as to have a 2 mm×2 mm light emitting part. At the time, the LiF film and the Al film were formed in a pattern so as to be orthogonal to the ITO film pattern.

Accordingly, the organic EL element was produced.

### Example 2

In the same manner as in the example 1 except that the smoothing layer was formed as follows, an organic EL element was produced.

(Formation of a Smoothing Layer)

A toluene solution of a copolymer of a polyfluorene derivative and a triphenyl amine was coated on the wettability changeable pattern by the spin coating method, and dried at 100° C. for 60 minutes. Thereby, a 30 nm film thickness smoothing layer was formed in a pattern.

Although the photocatalyst containing layer had the average surface roughness of 17 nm and the maximum height difference of 130 nm, by providing the smoothing layer, the average surface roughness became 8.9 nm, and the maximum height difference 60 nm.

### Example 3

In the same manner as in the example 1 except that the photocatalyst containing layer was formed as follows, an organic EL element was produced.

(Formation of a Photocatalyst Containing Layer)

By mixing the following components, a photocatalyst containing layer forming coating solution was prepared.

| | | |
|---|---|---|
| Titanium dioxide sol liquid (STS-01 produced | 3 | parts by weight |
| by ISHIHARA SANGYO KAISHA, LTD.) | | |
| Tetraethoxy silane | 1 | part by weight |
| 2 normal hydrochloric acid | 40 | parts by weight |
| Isopropyl alcohol | 75 | parts by weight |

By coating the photocatalyst containing layer forming coating solution with a spin coater and carrying out a drying process at 150° C. for 10 minutes, a 60 nm film thickness transparent photocatalyst containing layer was formed.

Next, by mixing the following components, a wettability changeable layer forming coating solution was prepared.

| | | |
|---|---|---|
| Fluoro alkoxy silane (MF-160E produced by | 0.3 | part by weight |
| Tohkem Co., Ltd.) | | |
| Isopropyl alcohol | 3 | parts by weight |

By coating the wettability changeable layer forming coating solution with a spin coater and carrying out a drying process at 150° C. for 10 minutes, a 20 nm film thickness transparent wettability changeable layer was formed.

By directing a light beam by a 70 mW/cm² illuminance for 240 seconds using a high pressure mercury lamp (254 nm, 365 nm) via a photo mask onto the wettability changeable layer, a wettability changeable pattern was formed.

Although the wettability changeable layer had the average surface roughness of 12 nm and the maximum height difference of 110 nm, by providing the smoothing layer, the average surface roughness became 5 nm, and the maximum height difference 40 nm.

### Comparative Example 1

In the same manner as in the example 1 except that the photocatalyst containing layer was formed as follows and the smoothing layer was not formed, an organic EL element was produced.

(Formation of a Photocatalyst Containing Layer)

By mixing the following components, a photocatalyst containing layer forming coating solution was prepared.

| | | |
|---|---|---|
| Titanium dioxide sol liquid (STS-01 produced | 3 | parts by weight |
| by ISHIHARA SANGYO KAISHA, LTD.) | | |
| Tetraethoxy silane | 1 | part by weight |
| 2 normal hydrochloric acid | 40 | parts by weight |
| Isopropyl alcohol | 75 | parts by weight |
| Fluoro alkoxy silane (MF-160E produced by | 0.3 | part by weight |
| Tohkem Co., Ltd.) | | |

By coating the photocatalyst containing layer forming coating solution with a spin coater and carrying out a drying process at 150° C. for 10 minutes, a 60 nm film thickness transparent photocatalyst containing layer was formed.

By directing a light beam by a 70 mW/cm² illuminance for 50 seconds using a high pressure mercury lamp (254 nm, 365 nm) via a photo mask onto the photocatalyst containing layer, a wettability changeable pattern was formed.

[Evaluation]

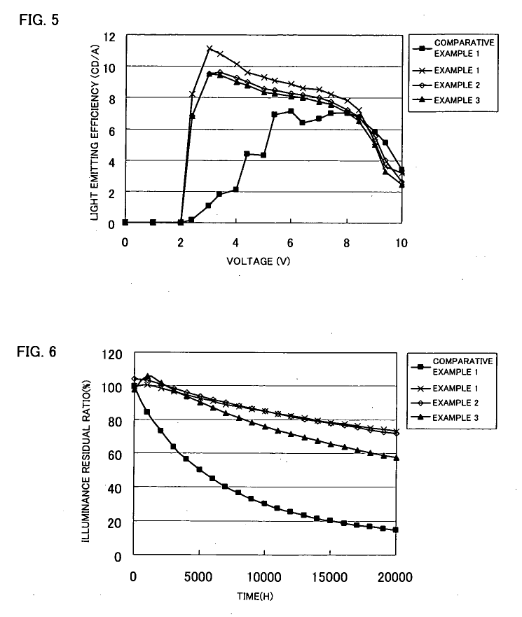

The light emitting efficiency-voltage characteristic and the life property of the organic EL elements of the examples 1 to 3 and the comparative example 1 are shown in FIGS. 5 and 6, respectively. As it is apparent from FIGS. 5 and 6, by forming the smoothing layer, the light emitting efficiency-voltage characteristic and the life property were improved.

### Example 4

(Formation of a Transparent Electrode)

An ITO film was formed by a 1,500 Å film thickness as a transparent electrode on a cleaned glass substrate by the sputtering method. Thereafter, the ITO film was patterned by the photolithography method so as to have a 300 μm line width and a 100 μm pitch.

(Formation of an Insulation Layer)

After coating a negative type resist (V259PA produced by Nippon Steel Chemical Co., Ltd.) on the substrate with the ITO film formed so as to have a 1 μm dry film thickness by a spin coating method, it was baked at 120° C. for 1 hour. Thereafter, it was exposed by a 100 μm width, centering the pitch portion without the ITO film via a photo mask with a 365 nm UV light beam by a 500 mJ exposure amount. At this time, a 1 mm gap between the photo mask and the substrate was provided. After developing the same with an organic alkaline developing agent (V2590D produced by Nippon Steel Chemical Co., Ltd.) for 40 seconds and by baking at 160° C. for 1 hour, an insulation layer was formed.

(Formation of a Photocatalyst Containing Layer)

By mixing the following components, a photocatalyst containing layer forming coating solution was prepared.

| | | |
|---|---|---|
| Titanium dioxide sol liquid (STS-01 produced | 3 | parts by weight |
| by ISHIHARA SANGYO KAISHA, LTD.) | | |
| Tetraethoxy silane | 1 | part by weight |
| 2 normal hydrochloric acid | 40 | parts by weight |
| Isopropyl alcohol | 75 | parts by weight |
| Fluoro alkoxy silane (MF-160E produced by | 7.5 | parts by weight |
| Tohkem Co., Ltd.) | | |

By coating the photocatalyst containing layer forming coating solution with a spin coater and carrying out a drying process at 150° C. for 10 minutes, a 60 nm film thickness transparent photocatalyst containing layer was formed.

By directing a light beam by a 70 mW/cm² illuminance for 50 seconds using a high pressure mercury lamp (254 nm, 365 nm) via a photo mask onto the photocatalyst containing layer, a wettability changeable pattern was formed.

(Formation of a Smoothing Layer)

A water dispersion of a PEDOT-PSS (poly(3,4-ethylene dioxythiophene)-polystyrene sulfonate) (product name; Baytron TP CH8000 produced by Bayer AG) was coated on the wettability changeable pattern by the ink jet method, and dried at 200° C. for 1 hour. Thereby, a 50 nm film thickness smoothing layer was formed in a pattern. The smoothing layer obtained had the average surface roughness of 7.9 nm and the maximum height difference of 50 nm.

(Formation of a Light Emitting Layer) Toluene solutions of a polyfluorene derivative for emitting a red light beam (ADS100RE produced by American dye Source, Inc.), a polyfluorene derivative for emitting a green light beam (ADS132GE produced by American Dye Source, Inc.), and a polyfluorene derivative for emitting a blue light beam (ADS135BE produced by American Dye Source, Inc.) were prepared, respectively. The solutions were coated onto the smoothing layer so as to be arranged alternately, using an ink jet coating device. Thereafter, by drying at 80° C. for 30 minutes, the light emitting layers of the three colors each of a 1,000 Å film thickness were formed in a pattern.

(Formation of a Metal Electrode)

Thereafter, a LiF film (film thickness 5 nm) and an Al film (film thickness 2,000 Å) were formed by the mask deposition method so as to have a 2 mm×2 mm light emitting part. At the time, the LiF film and the Al film were formed in a pattern so as to be orthogonal to the ITO film pattern.

Accordingly, an organic EL element was produced.

FIG. 4 is a schematic cross-sectional view showing the organic EL element accordingly produced. According to the organic EL element 20, an electrode layer (ITO electrode) 22 is formed in a pattern on a base material 21, and an insulation layer 23 is formed between the electrode layers 22. Furthermore, a photocatalyst containing layer 24 is formed on the entire surface on the electrode layer 22 and the insulation layer 23, a smoothing layer 25 is formed on the photocatalyst containing layer 24 in a region with the electrode layer 22 formed, and a light emitting layer (a red light emitting layer 26R, a green light emitting layer 26G and a blue light emitting layer 26B) is formed thereon. Then, a counter electrode layer (metal electrode) 27 is formed on the light emitting layers 26R, 26G and 26B, and the photo catalyst containing layer 24.

### Comparative Example 2

In the same manner as in the example 1 except that the photocatalyst containing layer was formed as follows and the smoothing layer in the example 4 was not formed, an organic EL element was produced.

(Formation of a Photocatalyst Containing Layer)

By mixing the following components, a photocatalyst containing layer forming coating solution was prepared.

| | | |
|---|---|---|
| Titanium dioxide sol liquid (STS-01 produced | 3 | parts by weight |
| by ISHIHARA SANGYO KAISHA, LTD.) | | |
| Tetraethoxy silane | 1 | part by weight |
| Fluoro alkoxy silane (MF-160E produced by | 7.5 | parts by weight |
| Tohkem Co., Ltd.) | | |
| Isopropyl alcohol | 75 | parts by weight |

By coating the photocatalyst containing layer forming coating solution with a spin coater, and carrying out a drying process at 150° C. for 10 minutes so as to proceed the hydrolysis and the polycondensation reaction, a 60 nm film thickness transparent photocatalyst containing layer, with the photocatalyst fixed firmly in the organosiloxane was formed.

By directing a light beam by a 70 mW/cm² illuminance for 50 seconds using a high pressure mercury lamp (254 nm, 365 nm) via a photo mask onto the photocatalyst containing layer, a wettability changeable pattern was formed.

[Evaluation]

The organic EL elements (organic EL displays) produced in the example 4 and the comparative example 2 were lit for the visual evaluation. In the same driving conditions, the device of the example 4 can be driven stably without display irregularity or short circuit between the electrodes.

What is claimed is:

1. A substrate for an organic electroluminescence element comprising a base material, an electrode layer formed on the base material, a photocatalyst containing layer formed on the electrode layer, and a smoothing layer formed on the photocatalyst containing layer.

2. The substrate for an organic electroluminescence element according to claim 1, wherein the smoothing layer has a charge transporting property.

3. The substrate for an organic electroluminescence element according to claim 1, wherein the photocatalyst containing layer is a photocatalyst containing wettability changeable layer containing a photocatalyst so as to have a wettability change by a function of the photocatalyst accompanied by an energy irradiation.

4. The substrate for an organic electroluminescence element according to claim 2, wherein the photocatalyst containing layer is a photocatalyst containing wettability changeable layer containing a photocatalyst so as to have a wettability change by a function of the photocatalyst accompanied by an energy irradiation.

5. The substrate for an organic electroluminescence element according to claim 1, wherein the photocatalyst containing layer comprises a photocatalyst processing layer containing a photocatalyst and a wettability changeable layer having a wettability change by a function of the photocatalyst accompanied by an energy irradiation.

6. The substrate for an organic electroluminescence element according to claim 2, wherein the photocatalyst containing layer comprises a photocatalyst processing layer containing a photocatalyst and a wettability changeable layer having a wettability change by a function of the photocatalyst accompanied by an energy irradiation.

7. The substrate for an organic electroluminescence element according to claim 1, wherein an average surface roughness (Ra) of the smoothing layer is less than 10 nm.

8. The substrate for an organic electroluminescence element according to claim 2, wherein an average surface roughness (Ra) of the smoothing layer is less than 10 nm.

9. The substrate for an organic electroluminescence element according to claim 1, wherein a maximum height difference (P−V) of the smoothing layer is less than 100 nm.

10. The substrate for an organic electroluminescence element according to claim 2, wherein a maximum height difference (P−V) of the smoothing layer is less than 100 nm.

11. An organic electroluminescence element comprising the substrate for an organic electroluminescence element according to claim 1, an organic electroluminescence layer formed on the smoothing layer of the substrate for an organic electroluminescence element and having at least a light emitting layer-, and a counter electrode layer formed on the organic electroluminescence layer.

12. An organic electroluminescence element comprising the substrate for an organic electroluminescence element according to claim 2, an organic electroluminescence layer formed on the smoothing layer of the substrate for an organic electroluminescence element and having at least a light emitting layer-, and a counter electrode layer formed on the organic electroluminescence layer.
